(19) United States
(12) Patent Application Publication
(10) Pub. No.: US 2025/0159882 A1
(43) Pub. Date: May 15, 2025

(54) FABRICATING SLIT STRUCTURES IN THREE-DIMENSIONAL SEMICONDUCTIVE DEVICES

(71) Applicant: Yangtze Memory Technologies Co., Ltd., Wuhan (CN)

(72) Inventor: Yonggang YANG, Wuhan (CN)

(21) Appl. No.: 18/389,704

(22) Filed: Dec. 19, 2023

(30) Foreign Application Priority Data
Nov. 9, 2023 (CN) 202311498996.9

(51) Int. Cl. H10B 43/27; H10B 43/10

(52) U.S. Cl. CPC H10B 43/27; H10B 43/10

(57) ABSTRACT

Systems, devices, and methods for fabricating slit structures in three-dimensional (3D) semiconductor devices are provided. In one aspect, a method includes providing a semiconductor structure including a first region including a first trench structure and a second region including a second trench structure, where the semiconductor structure includes a first sacrificial film covering the first trench structure, and a second sacrificial film formed on a surface of the second trench structure from an opening of the second trench structure to a bottom of the second trench structure along a first direction. At least one part of the second sacrificial film is etched, while at least one part of the first sacrificial film remains to cover the first trench structure.

### CROSS-REFERENCE TO RELATED APPLICATIONS

This application claims priority to Chinese Patent Application No. 202311498996.9, filed on Nov. 9, 2023, which is hereby incorporated by reference in its entirety.

### TECHNICAL FIELD

The present disclosure relates to semiconductor devices and fabrication processes for semiconductor devices.

### BACKGROUND

Semiconductor devices, e.g., memory devices, can have various structures to increase a density of memory cells and lines on a chip. For example, three-dimensional (3D) memory devices are attractive due to their capability to increase an array density by stacking more layers within a similar footprint. A 3D memory device normally includes a memory array of memory cells and peripheral circuits for facilitating operations of the memory array. The memory cells can include vertical structures.

### SUMMARY

The present disclosure describes methods, devices, systems and techniques for managing vertical structures in three-dimensional (3D) semiconductor devices.

One aspect of the present disclosure features a method including: providing a semiconductor structure including a first region including a first trench structure and a second region including a second trench structure, where the semiconductor structure includes a first sacrificial film covering the first trench structure, and a second sacrificial film formed on a surface of the second trench structure from an opening of the second trench structure to a bottom of the second trench structure along a first direction. At least one part of the second sacrificial film is etched, while at least one part of the first sacrificial film remains to cover the first trench structure.

In some implementations, the first trench structure is coupled to the second trench structure, and where the first sacrificial film is coupled to the second sacrificial film.

In some implementations, along a second direction perpendicular to the first direction, the first trench structure has a width smaller than the second trench structure.

In some implementations, the method includes depositing a sacrificial material over the first trench structure and the second trench structure to fill the sacrificial material in the first trench structure and form the first sacrificial film covering the filled sacrificial material in the first trench structure and to form the second sacrificial film having a first part on a top surface of the second region and a second part on an inner surface of the second trench structure.

In some implementations, the second sacrificial film includes a first part on a top surface of the second region and a second part on an internal surface of the second trench structure, and where etching the at least one part of the second sacrificial film includes etching the second part of the second sacrificial film away from the internal surface of the second trench structure.

In some implementations, the method includes changing at least one characteristic of a region of a sacrificial material, where the region of the sacrificial material includes at least one of the first sacrificial film or the first part of the second sacrificial film.

In some implementations, changing the at least one characteristic of the region of the sacrificial material includes implanting ions into the region of the sacrificial material to change an etching rate of the region of the sacrificial material.

In some implementations, implanting the ions into the region of the sacrificial material includes controlling at least one of an ion implanting power, an ion implanting angle, or an ion implanting density, to implant the ions into the region of the sacrificial material.

In some implementations, the sacrificial material includes at least one of polysilicon or aluminum oxide, and where the ions include at least one of nitrogen, argon, carbon, or boron.

In some implementations, a sacrificial material includes polysilicon, and the method further includes implanting ions into to a region of the sacrificial material to change the polysilicon in the region of the sacrificial material to non-polysilicon to thereby change an etching rate of the region of the sacrificial material, where the region of the sacrificial material includes the first part of the second sacrificial film on the top surface of the second region.

In some implementations, the second region includes a plurality of alternating sacrificial layers and insulating layers, and where the method further includes after etching the at least one part of the second sacrificial film, removing the sacrificial layers in the second region through the opening of the second trench structure.

Another aspect of the present disclosure features a semiconductor device, including: an array region including a first slit structure extending along a first direction; and a connection region adjacent to the array region along a second direction perpendicular to the first direction, where the connection region includes a second slit structure extending along the first direction through an insulating layer that extends along the second direction, and where the insulating layer includes an insulating material and ions distributed among the insulating material in the insulating layer.

In some implementations, the semiconductor device includes a stack of conductive layers and isolating layers alternating with each other along the first direction, where each of the first slit structure and the second slit structure extends through the stack of conductive layers and isolating layers, and where the insulating layer is closer to an end of the second slit structure than the stack of conductive layers and isolating layers along the first direction.

In some implementations, the connection region includes a plurality of contact structures extending through the stack of conductive layers and isolating layers, and at least one of the conductive layers is coupled to a corresponding contact structure of the plurality of contact structures.

In some implementations, the connection region includes first and second opposite ends along the first direction, and each of the plurality of contact structures is coupled out to a conductive contact at the first end or the second end.

In some implementations, the array region includes a plurality of channel structures extending through the stack of conductive layers and isolating layers.

In some implementations, the first slit structure connects the second slit structure along the second direction, and, along a third direction perpendicular to the first direction and the second direction, a width of the first slit structure is smaller than a width of the second slit structure.

In some implementations, the insulating layer includes a first surface and a second surface along the first direction, the first surface being closer to the end of the second slit structure along the first direction than the second surface, and where a first concentration of the ions adjacent to the first surface is higher than a second concentration of the ions adjacent to the second surface of the insulating layer.

A further aspect of the present disclosure features a method including providing a semiconductor structure including a first region including a first trench structure and a second region including a second trench structure, where the semiconductor structure includes a first sacrificial film covering the first trench structure, and a second sacrificial film formed on a surface of the second trench structure from an opening of the second trench structure to a bottom of the second trench structure, and where the second sacrificial film includes a first part on a top surface of the second region and a second part on an internal surface of the second trench structure. At least one characteristic of a region of a sacrificial material is changed, where the region of the sacrificial material includes at least one of the first sacrificial film or the first part of the second sacrificial film. The second part of the second sacrificial film is etched away from the internal surface of the second trench structure, while at least one part of the first sacrificial film remains to cover the first trench structure.

In some implementations, changing the at least one characteristic of the region of the sacrificial material includes implanting ions into the region of the sacrificial material to change an etching rate of the region of the sacrificial material.

Implementations of the present disclosure can provide one or more of the following technical advantages and/or benefits. For example, in some cases, a sacrificial material of a second trench structure can be etched while a sacrificial material of a first trench structure can remain or is etched slower or less than the sacrificial material of the second trench structure during the etching process. In some implementations, the techniques can use a protective layer to cover the sacrificial material of the first trench structure while exposing the sacrificial material of the second trench structure. In some implementations, the techniques described herein enable to implant ions into the sacrificial material of the first trench structure, and thereby lower the etching rate of the sacrificial material of the first trench structure. Therefore, the sacrificial material of the first trench structure can largely remain while the sacrificial material of the second trench structure is etched in the same etching process. The techniques based on ions implantation can simplify the fabrication process (e.g., the techniques can save the steps of depositing and removing the dedicated protective layer). Accordingly, the techniques can lower the fabrication costs of semiconductor structures. The techniques can also mitigate the oxide residual issues which are typical in the sacrificial material etching process. In some implementations, the techniques enable to extend the timing window of etching the sacrificial material, and thus simplify the fabrication process of semiconductor structures.

The techniques can be applied to various types of semiconductor devices, volatile memory devices, such as DRAM memory devices, or non-volatile memory (NVM) devices, such as NAND flash memory, NOR flash memory, resistive random-access memory (RRAM), phase-change memory (PCM) such as phase-change random-access memory (PCRAM), spin-transfer torque (STT)-Magnetoresistive random-access memory (MRAM), among others. The techniques can also be applied to charge-trapping based memory devices, e.g., silicon-oxide-nitride-oxide-silicon (SONOS) memory devices, and floating-gate based memory devices. The techniques can be applied to three-dimensional (3D) memory devices. The techniques can be applied to various memory types, such as SLC (single-level cell) devices, MLC (multi-level cell) devices like 2-level cell devices, TLC (triple-level cell) devices, QLC (quad-level cell) devices, or PLC (penta-level cell) devices. Additionally or alternatively, the techniques can be applied to various types of devices and systems, such as secure digital (SD) cards, embedded multimedia cards (eMMC), or solid-state drives (SSDs), embedded systems, among others.

The details of one or more implementations of the subject matter of this present disclosure are set forth in the accompanying drawings and the description below. Other features, aspects, and advantages of the subject matter will become apparent from the description, the drawings, and the claims.

### BRIEF DESCRIPTION OF THE DRAWINGS

The accompanying drawings, which are incorporated herein and form a part of the present disclosure, illustrate aspects of the present disclosure and, together with the description, further serve to explain the principles of the present disclosure and to enable a person of ordinary skill in the pertinent art to make and use the present disclosure.

FIG. 1A is a top view of an example 3D semiconductor structure.

FIG. 1B depicts cross-sectional views of the example 3D semiconductor structure along cut lines AA′ and BB′ shown in FIG. 1A.

FIGS. 2A-2E show cross-sectional views of structures of an example semiconductor structure after various stages of a fabrication process.

FIGS. 3A-3D show cross-sectional views of structures of an example semiconductor structure after various stages of a fabrication process.

FIG. 4 is a flow chart of an example process of forming a semiconductor structure.

FIG. 5 illustrates a block diagram of an example system having one or more semiconductor devices.

Like reference numbers and designations in the various drawings indicate like elements. It is also to be understood that the various exemplary implementations shown in the figures are merely illustrative representations and are not necessarily drawn to scale.

### DETAILED DESCRIPTION

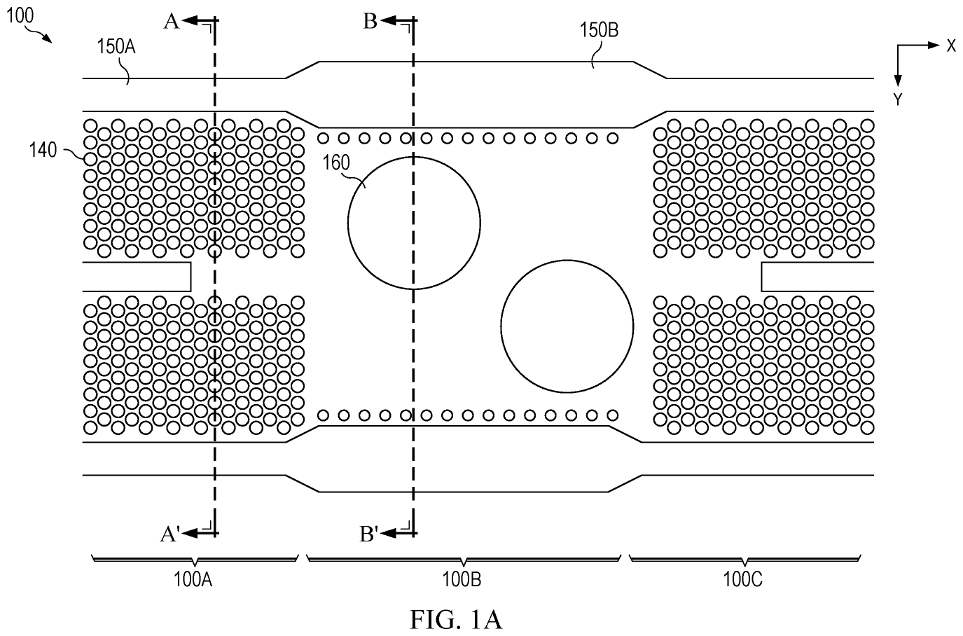

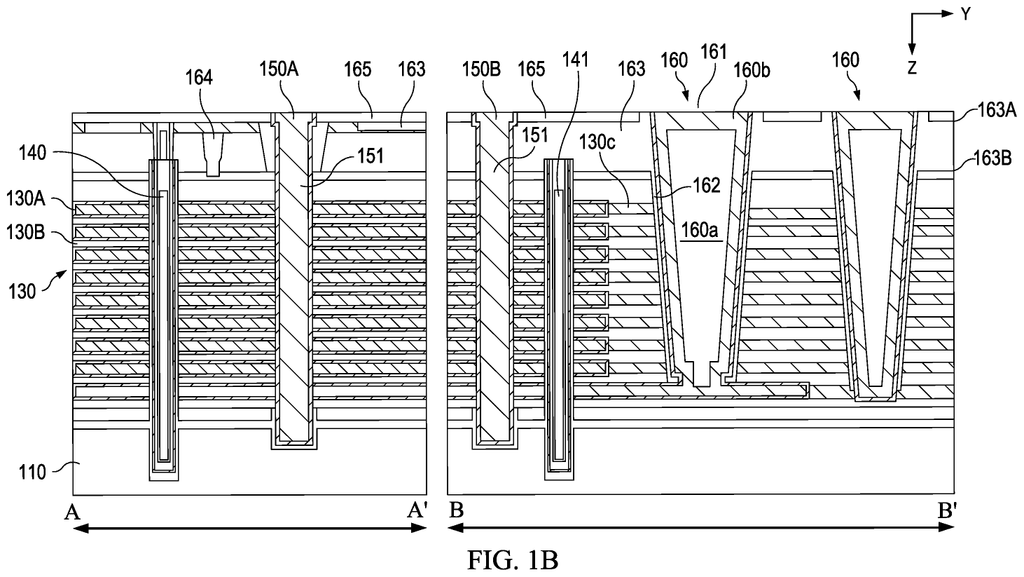

FIGS. 1A-1B illustrates an example 3D semiconductor structure 100, where FIG. 1A is a top view of the example 3D semiconductor structure 100, and FIG. 1B depicts cross-sectional views of the example 3D semiconductor structure 100 along cut lines AA′ and BB′ shown in FIG. 1A. The 3D semiconductor structure 100 can be used to form a memory device, e.g., a 3D NAND memory device.

In some implementations, as illustrated in FIG. 1A, the semiconductor structure 100 includes one or more array regions (e.g., an array region 100A, an array region 100C), and a connection region 100B configured to provide conductive connections for the one or more array regions, e.g., coupled to a control circuit. In some examples, the semiconductor structure 100 includes two array regions 100A, 100C, where the connection region 100B is between the two array regions along a first horizontal direction (e.g., X direction). Each array region 100A, 100C includes an array of channel structures 140. A channel structure 140 can be used to form a string of memory cells that can be coupled in serial along a vertical direction (e.g., Z direction) perpendicular to the first horizontal direction. A memory cell can include at least one vertical transistor. The vertical transistors of the memory cells can be stacked together along the second direction.

In some implementations, as illustrated in FIG. 1B, the semiconductor structure 100 includes a substrate 110 and a stack 130 of alternating conductive layers 130A and isolating layers 130B provided over the substrate 110. The substrate 110 can be any suitable semiconductor substrate having any suitable semiconductor materials, such as monocrystalline, polycrystalline or single crystalline semiconductors. For example, the substrate 110 can include silicon, silicon germanium (SiGe), germanium (Ge), gallium arsenide (GaAs), silicon on insulator (SOI), germanium on insulator (GOI), gallium nitride, silicon carbide, III-V compound, or any combinations thereof. Contact structures 160 can be formed within the connection region 100B. A contact structure 160 can be configured to connect a corresponding one of the conductive layers within the array region 100A and/or array region 100C, e.g., to a control circuit.

The stack 130 can extend in a second horizontal direction (e.g., the Y direction) that is parallel to a top surface of the substrate 110 and perpendicular to the first horizontal direction. The conductive layers 130A and the isolating layers 130B can alternate in the vertical direction (e.g., Z direction) perpendicular to the second horizontal direction. The conductive layers 130A can be the same or different from each other in thickness, for example, ranging from 10-500 nm, e.g., about 35 nm. The isolating layers 130B can also be the same or different from each other in thickness, for example, ranging from 10-500 nm, e.g., about 25 nm. It should be noted that the number of the conductive layers 130A and the isolating layers 130B shown in FIG. 1B is for illustration only and that any suitable number of the conductive layers 130A and the isolating layers 130B can be included in the stack 130 of the semiconductor structure 100. The conductive layers 130A can include any suitable conducting material, such as tungsten (W), cobalt (Co), copper (Cu), aluminum (Al), titanium nitride (TiN), polycrystalline silicon (polysilicon), doped silicon, silicides, or any combination thereof. The isolating layers 130B can include dielectric material, such as silicon oxide, silicon nitride, silicon oxynitride, or any combination thereof. In some implementations, the isolating layers 130B can also include high-k dielectric materials, such as hafnium oxide, zirconium oxide, aluminum oxide, tantalum oxide, lanthanum oxide, or any combination thereof.

One or more channel structures can be formed in the stack 130 through the conductive layers 130A and the isolating layers 130B of the stack 130 into the substrate 110. For example, as shown in FIG. 1B, a first channel structure 140 is formed within the array region 100A, and a second channel structure 141 is formed within the connection region 100B. In some examples, each of the first and second channel structures 140 and 141 can be in the shape of a cylinder or a pillar, and can include a high-k layer, a block layer surrounded by the high-k layer, a charge trapping layer (or a storage layer) surrounded by the block layer, a tunneling layer surrounded by the charge trapping layer, a channel layer surrounded by the tunneling layer, and a core filler layer surrounded by the channel layer, which extend through the conductive layers 130A and the isolation layer 130B of the stack 130, and a channel contact (not shown) formed above the core filler layer and being in contact with the channel layer. In some implementations, the channel layer can include silicon, such as amorphous silicon, polysilicon, or single crystalline silicon, the tunneling layer can include silicon oxide, silicon nitride, or any combination thereof, the blocking layer can include silicon oxide, silicon nitride, high-k dielectrics, or any combination thereof, and the charge trapping layer can include silicon nitride, silicon oxynitride, silicon, or any combination thereof. In some implementations, the tunneling layer, the charge trapping layer and the blocking layer, collectively referred to as a memory film, can include ONO dielectrics (silicon Oxide-silicon Nitride-silicon Oxide).

Each of the first and second channel structures 140 and 141 can be formed as follows: one or more channel openings (not shown) are formed subsequently by a combination of a photolithography process and an etching process to extend through sacrificial layers of the stack 130 and the isolating layer 130B of the stack 130 down into the substrate 110; and the high-k layer, the block layer, the charge trapping layer, the tunneling layer, the channel layer, the core filler layer and the channel contact can be formed within the channel openings subsequently. In some implementations, the sacrificial layers of the stack 130 within the array region 100A can be replaced with a conductive material, such as tungsten (W), to form conductive layers 130A of the 3D semiconductor structure 100. The conductive layers 130A can be used to form a stack of transistors of memory cells that can form a vertical memory cell string along the first channel structure 140. The first channel structure 140 can be connected to one or more metal layers (not shown) formed above the stack 130. In some implementations, the second channel structure 141 is a dummy channel structure and is used to support the conductive layers 130A and the isolation layers 130B of the stack 130 within the connection region 100B, and thus no metal layer is connected to the second channel structure 141.

One or more first slit structures 150A can be formed within the stack 130 of the array region 100A in the first horizontal direction (e.g., X direction) to divide the semiconductor structure 100 into a plurality of semiconductor blocks. Similarly, one or more second slit structures 150B can be formed in the connection region 100B in the first horizontal direction, to divide the semiconductor structure 100 into the plurality of semiconductor blocks. Corresponding first slit structure 150A and second slit structure 150B can be coupled to each other along the first horizontal direction, e.g., as illustrated in FIG. 1A. In some implementations, along the second horizontal direction (e.g., the Y direction as depicted in FIG. 1A), a width of the first slit structure 150A is smaller than a width of the second slit structure 150B. For example, a width of the second slit structure 150B can be approximately 1.5 to 2 times that of the first slit structure 150A. Each of the first slit structure(s) 150A and/or the second slit structure(s) 150B can extend through the stack 130 in the vertical direction (e.g., the Z direction) perpendicular to the first horizontal direction and the second horizontal direction, e.g., as illustrated in FIG. 1B.

In some implementations, a tetraethyl orthosilicate (TEOS) hard mask (not shown) can be deposited over the stack 130 in a deposition process, e.g., a chemical vapor deposition (CVD) process. A photoresist layer (not shown) can be applied over the TEOS hard mask and is patterned corresponding to trench locations within the stack 130. The stack 130 with the TEOS hard mask formed thereover can then be etched, whereby trench structures can be formed within the stack 130 to uncover the substrate 110 and lateral sides of the sacrificial layers and the isolating layers 130B of the stack 130 are exposed. The trench structures can then be filled with a trench filler material 151 (e.g., polysilicon) to form the first slit structures 150A and/or the second slit structures 150B.

One or more contact structures 160 can be formed within the connection region 100B to connect the conductive layers 130A of the 3D semiconductor structure 100. In some implementations, the connection region 100B includes a top end and a bottom end that are opposite along the Z direction, and each of the contact structure(s) 160 is coupled out to a conductive contact at the top end or the bottom end. In some implementations, a contact structure opening 161 can be formed to extend from a topmost one of the isolation layers 130B into a portion of the stack 130—which can include one or more conductive layers 130A and/or one or more isolation layers 130B—to reach a corresponding (or target) one of the conductive layers 130A to expose lateral sides of the portion of the stack 130. A spacer 162 can be formed to cover the lateral sides of the portion of the stack 130 and a top surface of the corresponding conductive layer 130A. Then, the spacer 162 covering the top surface of the desired conductive layer 130A can be removed, for example, by etching. A filling material (e.g., oxide) 160a and conductive material 160b (e.g., metal) 166 can be sequentially deposited through the contact structure opening 161 to form the contact structures 160.

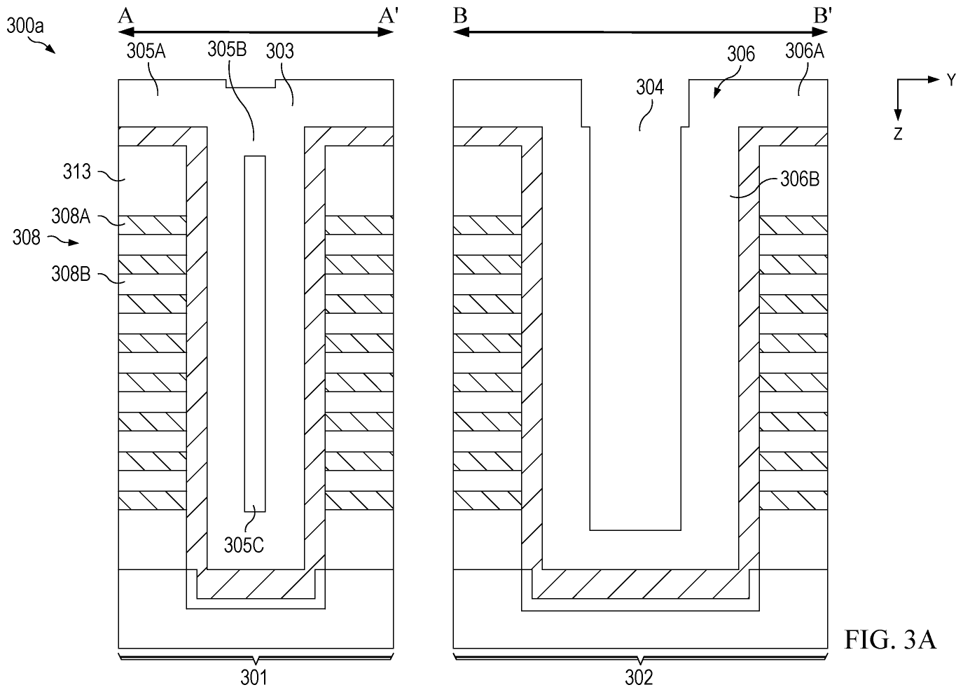

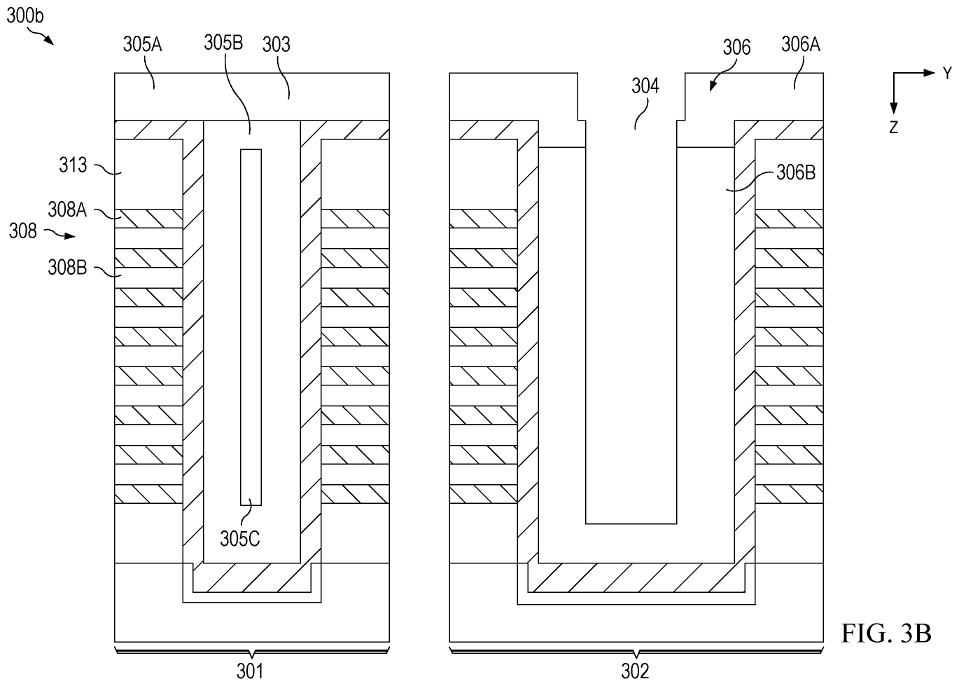

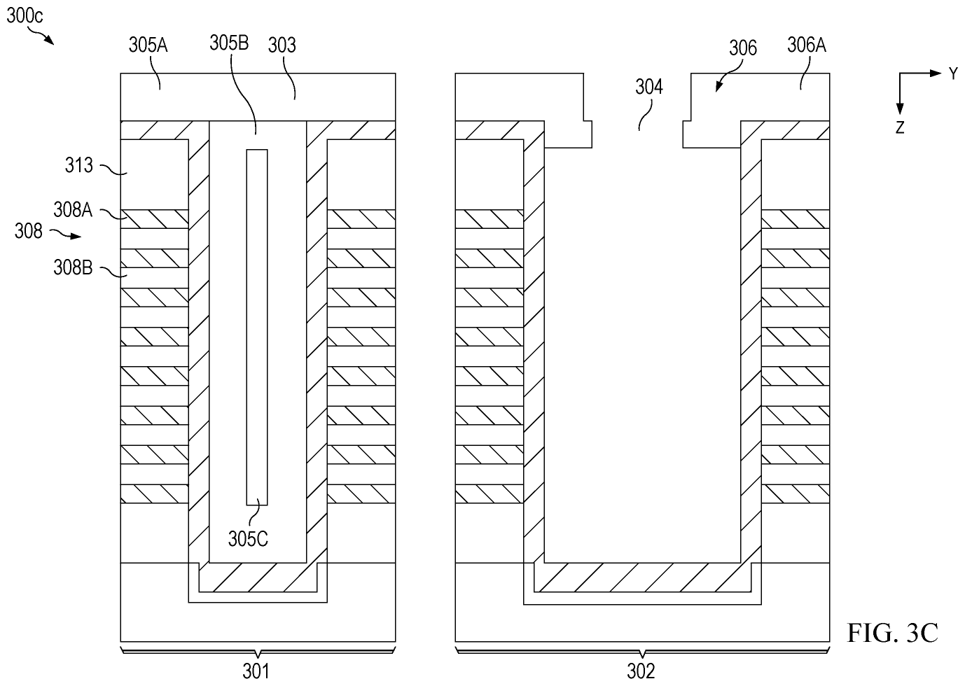

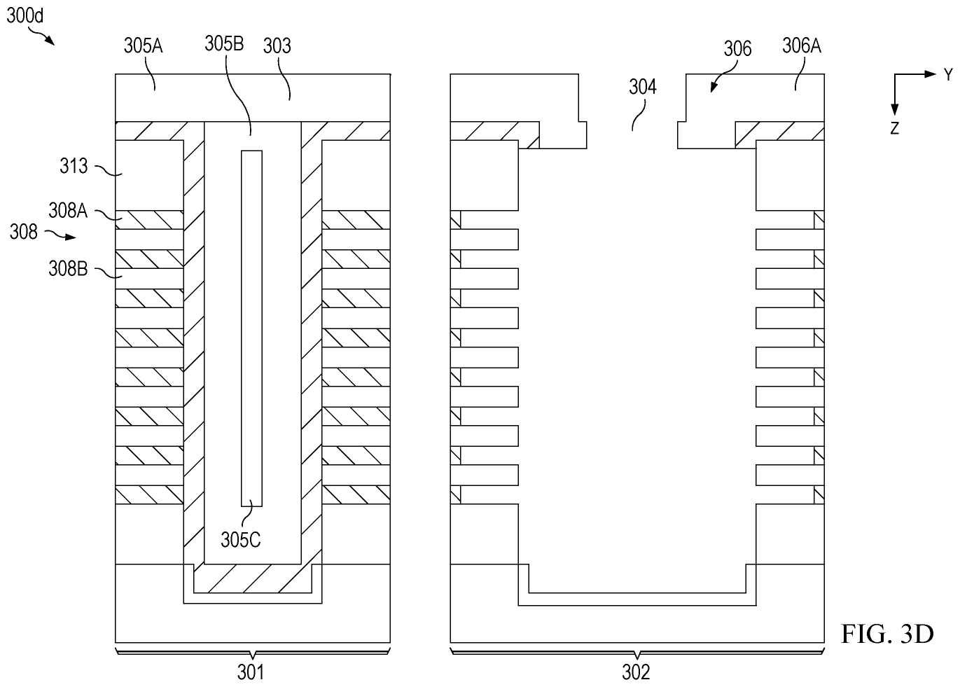

The 3D semiconductor structure 100 can include an insulation layer 163 deposited on top of the stack 130. The insulating layer 163 is closer to an end of the second slit structure 150B than the stack 130 along the Z direction. The insulating layer 163 can include a top surface 163A and a bottom surface 163B along the Z direction. The top surface 163A is closer to the end of the second slit structure 150B along the Z direction than the bottom surface 163B. In some cases, ions can be implanted from the top surface 163A of the insulation layer 163 during a fabrication process of the second slit structure 150B (e.g., as described with further details with respect to FIGS. 3A-3D). As a result, the insulation layer 163 can include ions distributed among the insulating material in the insulating layer 163. In some cases, the ions include at least one of nitrogen, argon, carbon, or boron. In some examples, a concentration of the ions in the insulating material of the insulation layer 163 is about 10⁻¹⁴ cm³. In some implementations, as the ions are implanted from the top surface 163A of the insulation layer 163, the concentration of ions can decrease along the Z direction from the top surface 163A to the bottom surface 163B. In other words, a concentration of the ions adjacent to the top surface 163A can be higher than a concentration of the ions adjacent to the bottom surface 163B.

In some implementations, the semiconductor structure 100 includes one or more top selected gates (TSGs) 164. The semiconductor structure 100 can be formed with the following steps. A stack of alternating dielectric layers 130C and isolating layers 130B is formed. After forming the stack of alternating dielectric layers 130C and isolating layers 130B, an insulating layer (e.g., polysilicon) 163 can be formed over the stack. A first portion of the insulating layer 163 in the connection region 100B is etched away, while a second portion of the insulating layer 163 in the array region 100A remains. Then, the one or more TSGs 164 are formed in the array region 100A based on the second portion of the insulating layer 163 in the array region 100A. After that, a dielectric material 165 is deposited on top of the etched insulating layer 163. As shown in FIG. 1B, as the first portion of the insulating layer 163 was etched away, a thickness of a layer of the dielectric material 165 in the connection region 100B is greater than a thickness of a layer of the dielectric material 165 over the TSGs 164 in the array region 100A.

In some implementations, the semiconductor structure 100 can be used to form a memory device by one or more further processing steps. For example, on a first side of the semiconductor structure 100, the substrate 110 can be thinned or removed, e.g., to expose the conductive material (e.g., polysilicon or metal) in the channel structures (e.g., the channel structures 140) and/or slit structures (e.g., the slit structures 150A and 150B). A conductive material (e.g., metal) can be deposited on the exposed conductive material to form a common source layer, where the strings of memory cells and/or slit structures can be conductively coupled to the common source layer.

On a second side of the semiconductor structure 100 that is opposite to the first side, the semiconductor structure 100 can be integrated with a control structure (e.g., a CMOS wafer or die) including a control circuit. For example, a surface of the second side of the semiconductor structure 100 can be bonded with a surface of the control circuit of the control structure.

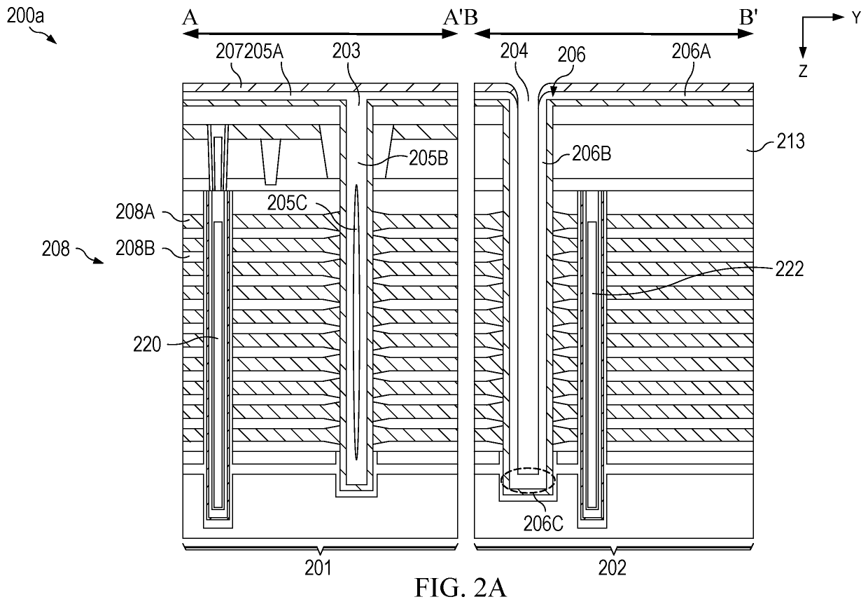

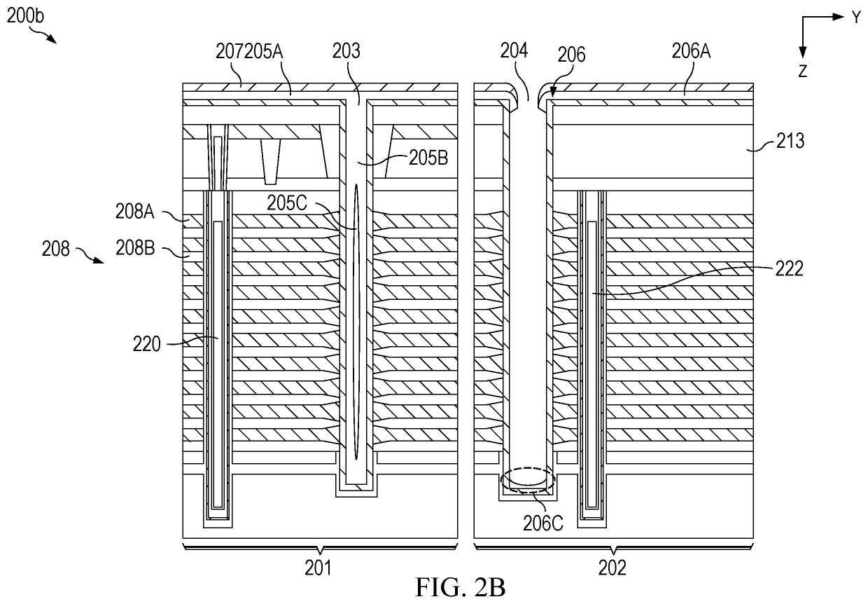

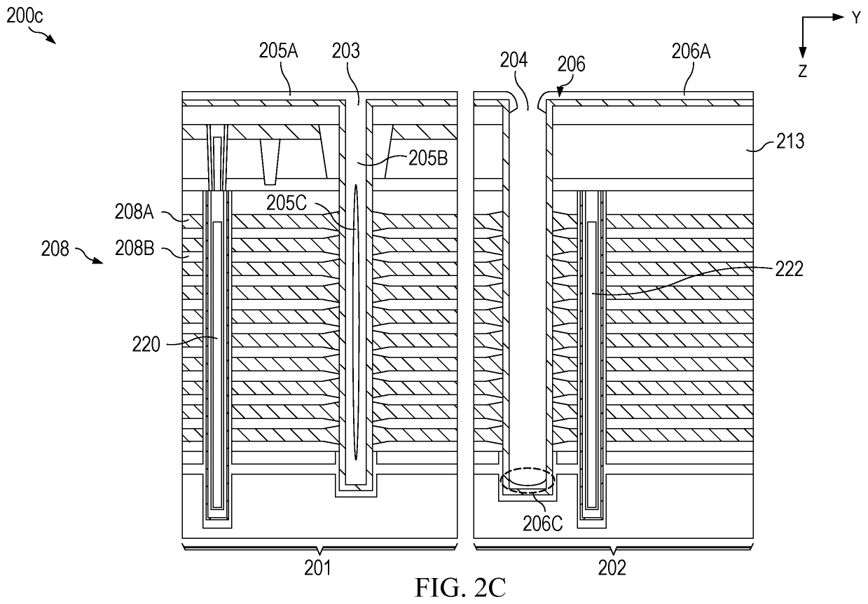

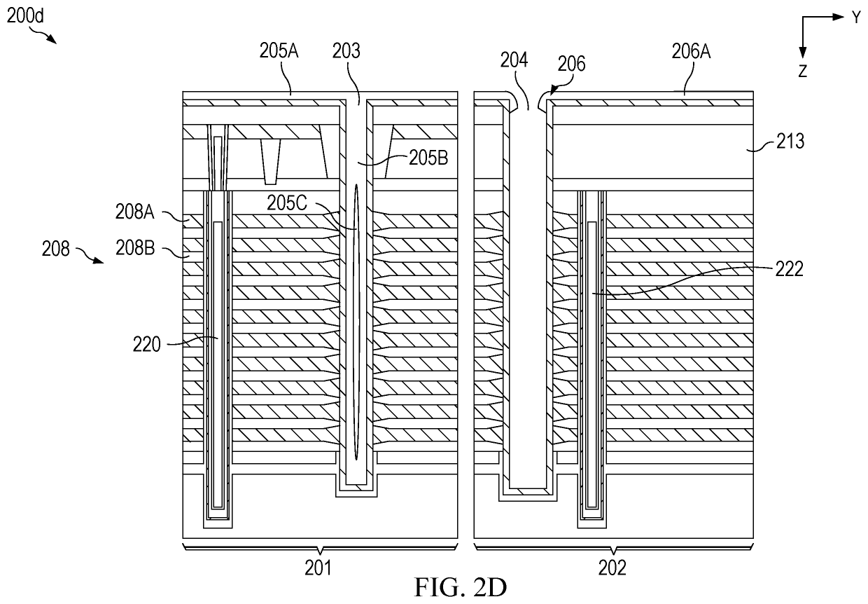

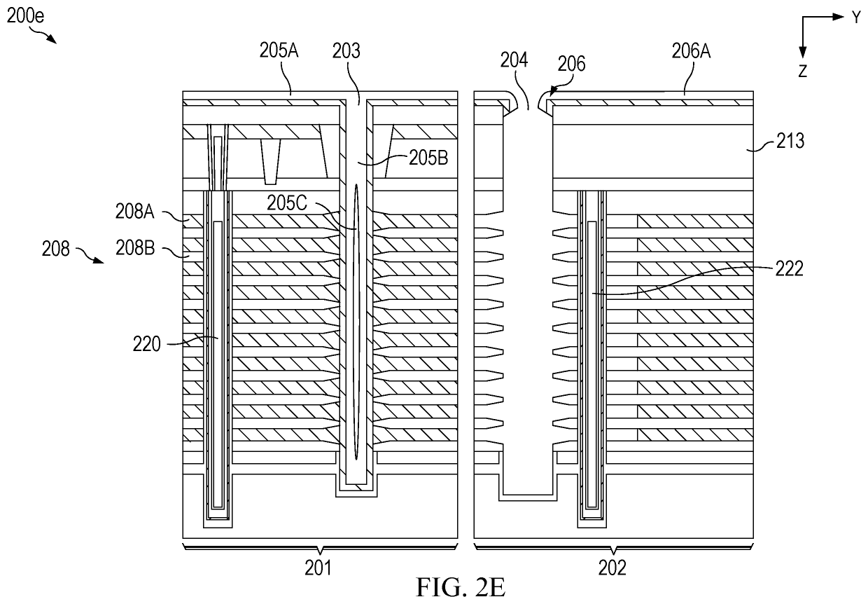

FIGS. 2A-2E show cross-sectional views of structures of an example semiconductor structure after various stages of a fabrication process. The semiconductor structure can be similar to, or same as, the 3D semiconductor structure 100 of FIGS. 1A-1B, or a part of the 3D semiconductor structure 100. FIGS. 2A-2E are cross-sectional views from similar, or the same, perspective as FIG. 1B (e.g., along cut lines AA′ and BB′ shown in FIG. 1A).

FIG. 2A shows a structure 200a after a first stage of forming the semiconductor structure. The first stage includes, for example, providing a semiconductor structure including a first region 201 and a second region 202, and depositing a protective layer 207 on the semiconductor structure. In some implementations, the first region 201 includes a first trench structure 203, and the second region includes a second trench structure 204. In some cases, the first region 201 includes an array region (e.g., corresponding to the array region 100A or 100C of FIGS. 1A-1B), and the first trench structure 203 is in the array region. In some cases, the second region 202 includes a connection region (e.g., corresponding to the connection region 100B of FIGS. 1A-1B), and the second trench structure 204 is in the connection region. The first trench structure 203 can be used to form a slit structure (e.g., the first slit structure 150A of FIGS. 1A-1B) in the first region 201. The second trench structure 204 can be used to form a slit structure (e.g., the second slit structure 150B of FIGS. 1A-1B) in the second region 202.

In some examples, the second region 202 is adjacent to the first region 201 along a first horizontal direction (e.g., the X direction) perpendicular to the vertical direction. In some cases, the first trench structure 203 is coupled to (e.g., contacts, connects, etc.) the second trench structure 204. In some cases, along a second horizontal direction (e.g., the Y direction), the first trench structure 203 has a width smaller than the second trench structure 204. In some examples, a width of the second trench structure 204 is 1.5 to 2 times greater than a width of the first trench structure.

In some implementations, before depositing the protective layer 207, a sacrificial material is deposited over the first trench structure 203 to fill the sacrificial material in the first trench structure 203 to form a first sacrificial film 205A and filled sacrificial material 205B in the first trench structure 203. The first sacrificial film 205A can cover the filled sacrificial material 205B, and thus cover the first trench structure 203. An air gap 205c may be formed in the filled sacrificial material 205B inside the first trench structure 203. Additionally, the sacrificial material is deposited over the second trench structure 204 to form the second sacrificial film 206 having a first part 206A on a top surface of the second region 202, a second part 206B on an inner surface of the second trench structure 204, and a third part 206C at the bottom of the second trench structure 204. The second sacrificial film 206 is formed on a surface of the second trench structure 204 from an opening of the second trench structure 204 to a bottom of the second trench structure 204 along a vertical direction (e.g., the Z direction as depicted in FIG. 1B). The sacrificial material can include any suitable sacrificial material, such as oxide, carbon, polysilicon, or combinations thereof. The first sacrificial film 205A can be coupled to (e.g., contacts, connects, etc.) the second sacrificial film 206. Note that, the width of the second trench structure 204 and the width of the first trench structure 203 are configured such that the sacrificial material can fill the opening of the first trench structure 203 to form the filled sacrificial material 205B, but cannot cover the opening of the second trench structure 204.

As noted, a protective layer 207 can be deposited on the structure 200a. The protective layer 207 can form a layer on the first sacrificial film 205A. Additionally, the protective layer 207 can form on the first part 206A of the second sacrificial film 206, whereas the opening of the second trench structure 204 remains open. For example, in some cases, the protective layer 207 does not cover the second part 206B and/or the third part 206C of the second sacrificial film 206. The protective layer 207 can include one or more materials such as organic titanium.

The structure 200a can include a stack 208 of alternating sacrificial layers 208A and isolating layers 208B. As described below, the stack 208 can be used to form a stack of alternating conductive layers and isolating layers, e.g., the stack 130 of FIG. 1B. The sacrificial layer 208A can include a sacrificial material. The sacrificial material can include an insulating material (e.g., silicon dioxide, silicon nitride, carbon), a semiconducting material (e.g., silicon, gallium arsenide), or others.

In some implementations, one or more first channel structures 220 (e.g., the first channel structure 140 of FIGS. 1A-1B) are formed in the first region 201, penetrating through the stack 208. One or more second channel structures 222 (e.g., the second channel structure 141 of FIGS. 1A-1B) are formed in the second region 202, penetrating through the stack 208. An insulating layer 213 (e.g., the insulating layer 163 of FIG. 1B) can be formed on top of the stack 208.

FIG. 2B shows a structure 200b after a second stage of forming the semiconductor structure. The second stage includes, for example, etching the second part 206B of the second sacrificial film 206 away from the internal surface of the second trench structure 204, while at least one part of the first sacrificial film 205A remains to cover the first trench structure 203. The protective layer 207 can be configured to prevent the materials beneath the protective layer 207 from being etched (e.g., by preventing the materials beneath the protective layer 207 from contacting the etchants). Therefore, depositing the protective layer 207 over selective areas can selectively remove materials-removing materials not covered by the protective layer 207, while largely keeping the materials beneath the protective layer 207. In this case, the protective layer 207 covers the first sacrificial film 205A and the first part 206A of the second sacrificial film 206, whereas the protective layer 207 does not cover the second part 206B and the third part 206C of the second sacrificial film 206. As a result, the second part 206B of the second sacrificial film 206 can be etched away, while the first sacrificial film 205A can remain to cover the first trench structure 203. In some cases, the second part 206B of the second sacrificial film 206 can be etched using, for example, tetramethylammonium hydroxide (TMAH).

FIG. 2C shows a structure 200c after a third stage of forming the semiconductor structure. The third stage includes, for example, removing the protective layer 207. The protective layer 207 can be removed using, for example, an asher method or other suitable material removal process.

FIG. 2D shows a structure 200d after a fourth stage of forming the semiconductor structure. The fourth stage includes, for example, removing the third part 206C of the second sacrificial film 206 located at the bottom of the second trench structure 204. The third part 206C of the second sacrificial film 206 can be etched away using, for example, TMAH.

FIG. 2E shows a structure 200e after a fifth stage of forming the semiconductor structure. The fifth stage includes, for example, removing the sacrificial material of the sacrificial layers 208A of the stack 208 in the second region 202. In some cases, the sacrificial material can be removed using a material removal process, such as a wet method, an asher method, or other suitable methods. For example, the sacrificial material in the sacrificial layers 208A can be removed through the opening of the second trench structure 204 (e.g., etchants can be instilled into the second trench structure 204 through the opening of the second trench structure 204). Removing the sacrificial material can result in cavities (or recesses) in the sacrificial layers 208A. Conducting materials (e.g., tungsten) can then be filled in the cavities to form conductive layers (e.g., the conductive layers 130A as depicted in FIG. 1B), thereby generating an alternating stack of conductive layers and isolation layers (e.g., the stack 130 of FIG. 1B). In some examples, a part of the sacrificial material is not removed to provide support of the structure 200e during one or more subsequent fabrication process steps.

FIGS. 3A-3D show cross-sectional views of structures of an example semiconductor structure after various stages of a fabrication process. The semiconductor structure can be similar to, or same as, the 3D semiconductor structure 100 of FIGS. 1A-1B, or a part of the 3D semiconductor structure 100. FIGS. 3A-3D are cross-sectional views from similar, or the same, perspective as FIG. 1B (e.g., along cut lines AA′ and BB′ shown in FIG. 1A). In some cases, the fabrication process described with respect to FIGS. 3A-3D and the fabrication process described with respect to FIGS. 2A-2E are two different fabrication processes used to fabricate a similar semiconductor structure.

FIG. 3A shows a structure 300a after a first stage of forming the semiconductor structure. In some cases, the structure 300a does not include the protective layer 207 included in the structure 200a of FIG. 2A. The first stage includes, for example, providing a semiconductor structure including a first region 301 and a second region 302. In some implementations, the first region 301 includes a first trench structure 303 (e.g., the first trench structure 203 of FIG. 2A), and the second region 302 includes a second trench structure 304 (e.g., the second trench structure 204 of FIG. 2A). In some cases, the first region 301 includes an array region (e.g., corresponding to the array region 100A or 100C of FIGS. 1A-1B), and the first trench structure 303 is in the array region. In some cases, the second region 302 includes a connection region (e.g., corresponding to the connection region 100B of FIGS. 1A-1B), and the second trench structure 304 is in the connection region. The first trench structure 303 can be used to form a slit structure (e.g., the first slit structure 150A of FIGS. 1A-1B) in the first region 301. The second trench structure 304 can be used to form a slit structure (e.g., the second slit structure 150B of FIGS. 1A-1B) in the second region 302.

In some examples, the second region 302 is adjacent to the first region 301 along a first horizontal direction (e.g., the X direction) perpendicular to the vertical direction. In some cases, the first trench structure 303 is coupled to (e.g., contacts, connects, etc.) the second trench structure 304. In some cases, along a second horizontal direction (e.g., the Y direction), the first trench structure 303 has a width smaller than the second trench structure 304. In some examples, a width of the second trench structure 304 is 1.5 to 2 times greater than a width of the first trench structure.

In some implementations, a sacrificial material is deposited over the first trench structure 303 to fill the sacrificial material in the first trench structure 303 to form a first sacrificial film 305A and filled sacrificial material 305B in the first trench structure 303. The first sacrificial film 305A can cover the filled sacrificial material 305B, and thus cover the first trench structure 303. An air gap 305c may be formed in the filled sacrificial material 305B inside the first trench structure 303. Additionally, the sacrificial material is deposited over the second trench structure 304 to form the second sacrificial film 306 having a first part 306A on a top surface of the second region 302, and a second part 306B on an inner surface (including bottom) of the second trench structure 304. The second sacrificial film 306 is formed on a surface of the second trench structure 304 from an opening of the second trench structure 304 to a bottom of the second trench structure 304 along a vertical direction (e.g., the Z direction as depicted in FIG. 1B). The sacrificial material can include any suitable sacrificial materials, such as oxide, carbon, polysilicon, or combinations thereof. The first sacrificial film 305A can be coupled to (e.g., contacts, connects, etc.) the second sacrificial film 306. Note that, the width of the second trench structure 304 and the width of the first trench structure 303 are configured such that the sacrificial material can fill the opening of the first trench structure 303 to form the filled sacrificial material 305B, but cannot cover the opening of the second trench structure 304.

The structure 300a can include a stack 308 of alternating sacrificial layers 308A and isolating layers 308B. As described below, the stack 308 can be used to form a stack of alternating conductive layers and isolating layers, e.g., the stack 130 of FIG. 1B. The sacrificial layer 308A can include a sacrificial material. The sacrificial material can include an insulating material (e.g., silicon dioxide, silicon nitride, or carbon), a semiconducting material (e.g., silicon or gallium arsenide), or others. In some implementations, an insulating layer 313 (e.g., the insulating layer 163 of FIG. 1B) can be formed on top of the stack 308.

FIG. 3B shows a structure 300b after a second stage of forming the semiconductor structure. The second stage includes, for example, changing at least one characteristic of a region of a sacrificial material. The region of the sacrificial material can include, for example, at least one of the first sacrificial film 305A or the first part 306A of the second sacrificial film 306. In some cases, changing the at least one characteristic of the region of the sacrificial material includes implanting ions into the region of the sacrificial material to change an etching rate of the region of the sacrificial material. In some implementations, a first etching rate of the sacrificial material with the implanted ions is smaller than a second etching rate of sacrificial material without implanted ions. In some examples, a ratio of the first etching rate and the second etching rate is about 1/8. An etching rate can determine a speed at which material is removed during an etching process. For example, a higher etching rate can correspond to a higher etching speed, whereas a lower etching rate can correspond to a lower etching speed. Accordingly, implanting ions in selective regions can be used to selectively remove materials-removing materials that do not have the ions implanted, while largely keeping the materials having the ions implanted.

In some implementations, implanting the ions into the region of the sacrificial material includes controlling at least one of an ion implanting power, an ion implanting angle, or an ion implanting density, to implant the ions into the region of the sacrificial material. In some examples, controlling the at least one of the ion implanting power, the ion implanting angle, or the ion implanting density, to implant the ions into the region of the sacrificial material includes controlling to implant the ions in the region of the sacrificial material, without implanting the ions into the filled sacrificial material 305B and into the second part 306B of the second sacrificial film. By doing so, the etching rate of the region of the sacrificial material with the implanted ions can be different from (e.g., lower than) that of the sacrificial material in the filled sacrificial material 305B or the second part 306B of the second sacrificial film 306. By controlling the etching rates in different regions, it is possible to remove some material(s) while protecting other materials from being removed. For example, if the etching rate of the region of the sacrificial material with the implanted ions is lower than that of the sacrificial material in the second part 306B of the second sacrificial film 306, at least a part of the region of the sacrificial material with the implanted ions can remain while the sacrificial material in the second part 306B of the second sacrificial film 306 can be removed (e.g., completely) during the etching process.

The sacrificial material and the ions can include any suitable materials and/or elements. In some examples, the sacrificial material includes at least one of polysilicon or aluminum oxide, and the ions include at least one of nitrogen, argon, carbon, or boron. For example, if the sacrificial material includes polysilicon, the ions can be implanted into a region of the sacrificial material to change the polysilicon in the region of the sacrificial material to non-polysilicon to thereby change an etching rate of the region of the sacrificial material, where the region of the sacrificial material includes the first part 306A of the second sacrificial film 306 on the top surface of the second region 302. In some other examples, the sacrificial material includes silicon nitride, and the ions can include nitrogen.

FIG. 3C shows a structure 300c after a third stage of forming the semiconductor structure. The third stage includes, for example, etching the second part 306B of the second sacrificial film 306 away from the internal surface of the second trench structure 304, while at least one part of the first sacrificial film 305A remains to cover the first trench structure 303. As noted, this can be achieved because the second part 306B of the second sacrificial film 306 has a higher etching rate than that of the first sacrificial film 305A. In some cases, the first part 306A of the second sacrificial film 306 can be implanted with ions, and thus at least a part of the first part 306A of the second sacrificial film 306 can also remain when the second part 306B of the second sacrificial film 306 is etched away.

FIG. 3D shows a structure 300d after a fourth stage of forming the semiconductor structure. The fourth stage includes, for example, removing sacrificial material of the sacrificial layers 308A in the second region 302, e.g., similar to the fifth stage of FIG. 2E. In some cases, the sacrificial material can be removed using a material removal process, such as a wet method, an asher method, or other suitable methods. For example, the sacrificial material in the sacrificial layers 308A can be removed through the opening of the second trench structure 304 (e.g., etchants can be instilled in the second trench structure 304 through the opening of the second trench structure 304). Removing the sacrificial material can result in cavities in the sacrificial layers 308A. Conducting materials (e.g., tungsten) can then be filled in the cavities to form conductive layers (e.g., the conductive layers 130A as depicted in FIG. 1B), thereby generating an alternating stack of conductive layers and isolation layers (e.g., the stack 130 of FIG. 1B). In some examples, a part of the sacrificial material is not removed to provide support of the semiconductor structure 300d during the fabrication process.

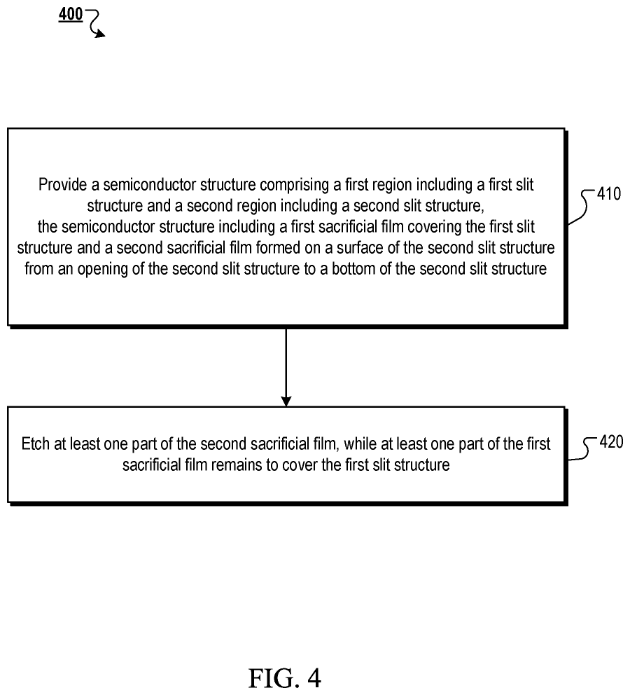

FIG. 4 is a flow chart of an example process 400 of forming a semiconductor structure. The semiconductor structure can be similar to, or same as, the semiconductor structure 100 of FIGS. 1A-1B, or a part of the semiconductor structure 100. The process 400 can be described in view of FIGS. 1A-1B. The process 400 can include the fabrication process of forming the semiconductor structure in FIGS. 2A-2E or FIGS. 3A-3D. The process 400 includes steps that can be performed with any suitable order and/or any combination.

At step 410, a semiconductor structure including a first region and a second region is provided. The first region (e.g., the first region 201 of FIG. 2A or the first region 301 of FIG. 3A) can include a first trench structure (e.g., the first trench structure 203 of FIG. 2A or the first trench structure 303 of FIG. 3A), and the second region (e.g., the second region 202 of FIG. 2A or the second region 302 of FIG. 3A) can include a second trench structure (e.g., the second trench structure 204 of FIG. 2A or the second trench structure 304 of FIG. 3A). The semiconductor structure can include a first sacrificial film (e.g., the sacrificial film 205A of FIG. 2A or 305A of FIG. 3A) covering the first trench structure and a second sacrificial film (e.g., the sacrificial film 206 of FIG. 2A or 306 of FIG. 3A) formed on a surface of the second trench structure from an opening of the second trench structure to a bottom of the second trench structure along a first direction (e.g., Z direction). In some cases, the first region includes an array region, the second region includes a connection region. The first trench structure is in the array region, and the second trench structure is in the connection region. In some implementations, the first trench structure is coupled to the second trench structure, and the first sacrificial film is coupled to the second sacrificial film. In some examples, along a second direction (e.g., Y direction) perpendicular to the first direction, the first trench structure has a width smaller than the second trench structure.

In some implementations, the example process 400 includes depositing a sacrificial material over the first trench structure and the second trench structure to fill the sacrificial material in the first trench structure and form the first sacrificial film covering the filled sacrificial material (e.g., 205B of FIG. 2A or 305B of FIG. 3A) in the first trench structure and to form the second sacrificial film having a first part (e.g., 206A of FIG. 2A or 306A of FIG. 3A) on a top surface of the second region and a second part (e.g., 206B of FIG. 2A or 306B of FIG. 3A) on an inner surface of the second trench structure, e.g., as illustrated in FIG. 2A or FIG. 3A.

In some implementations, the example process 400 includes changing at least one characteristic of a region of a sacrificial material, where the region of the sacrificial material includes at least one of the first sacrificial film (e.g., 305A of FIG. 3A) or the first part (e.g., 306A of FIG. 3A) of the second sacrificial film, e.g., as illustrated in FIG. 3A. In some examples, changing the at least one characteristic of the region of the sacrificial material includes implanting ions into the region of the sacrificial material to change an etching rate of the region of the sacrificial material. In some examples, implanting the ions into the region of the sacrificial material includes controlling at least one of an ion implanting power, an ion implanting angle, or an ion implanting density, to implant the ions into the region of the sacrificial material. In some cases, controlling the at least one of the ion implanting power, the ion implanting angle, or the ion implanting density, to implant the ions into the region of the sacrificial material includes controlling to implant the ions in the region of the sacrificial material, without implanting the ions into the first trench structure and into the second part of the second sacrificial film.

In some examples, a ratio of the etching rate of the region of the sacrificial material with the implanted ions and an etching rate of the second part of the second sacrificial film is about 1/8. In some implementations, the sacrificial material includes at least one of polysilicon or aluminum oxide, and where the ions include at least one of nitrogen, argon, carbon, or boron. In some implementations, a sacrificial material includes polysilicon, and the method further includes implanting ions into a region of the sacrificial material to change the polysilicon in the region of the sacrificial material to non-polysilicon to thereby change an etching rate of the region of the sacrificial material, where the region of the sacrificial material includes the first part of the second sacrificial film on the top surface of the second region. In some implementations, the sacrificial material includes silicon nitride, and where the ions include nitrogen.

In some cases, before etching the second part of the second sacrificial film, the process 400 includes depositing a protective layer on the semiconductor structure, where the protective layer forms a layer on the first sacrificial film, and the opening of the second trench structure remains open with the protective layer on the first part of the second sacrificial film, e.g., as illustrated in FIG. 2A. In some implementations, the protective layer includes organic titanium. In some examples, the example process 400 includes after etching the second part of the second sacrificial film, removing the protective layer from the semiconductor structure.

At step 420, at least one part of the second sacrificial film is etched, while at least one part of the first sacrificial film remains to cover the first trench structure. In some cases, the second sacrificial film includes a first part on a top surface of the second region and a second part on an internal surface of the second trench structure, and etching the at least one part of the second sacrificial film includes etching the second part of the second sacrificial film away from the internal surface of the second trench structure, e.g., as illustrated in FIG. 2B or 3B. In some cases, the second region includes a plurality of alternating sacrificial layers and insulating layers, and the example process 400 can further include: after etching the at least one part of the second sacrificial film, removing the sacrificial layers in the second region through the opening of the second trench structure, e.g., as illustrated in FIG. 2E or 3D.

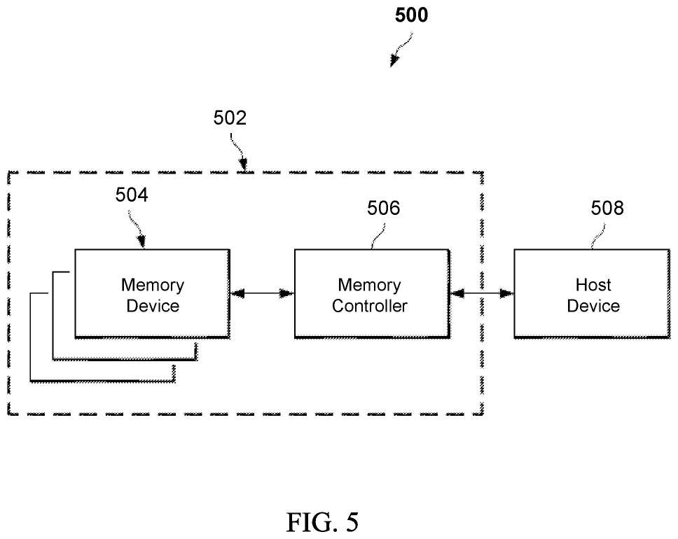

FIG. 5 illustrates a block diagram of a system 500 having one or more semiconductor devices (e.g., memory devices), according to one or more implementations of the present disclosure. The system 500 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 5, the system 500 can include a host device 508 and a memory system 502 having one or more 3D memory devices 504 and a memory controller 506. Host device 508 can include a processor of an electronic device, such as a central processing unit (CPU), or a system-on-chip (SoC), such as an application processor (AP). Host device 508 can be configured to send or receive data to or from the one or more 3D memory devices 504.

A 3D memory device 504 can be any 3D memory device disclosed herein, such as 3D memory device depicted in FIGS. 1A-1B, 3D memory device based on the semiconductor structures 200a-200c of FIGS. 2A-2E, or 3D memory device based on the semiconductor structures 300a-300d of FIGS. 3A-3D. In some implementations, a 3D memory device 504 includes a NAND Flash memory. Memory controller 506 (a.k.a., a controller circuit) is coupled to 3D memory device 504 and host device 508. Consistent with implementations of the present disclosure, 3D memory device 504 can include a plurality of conductive interconnections through a cover layer that are in contact with conductive pads in a conductive pad layer, and memory controller 506 can be coupled to 3D memory device 504 through at least one of the plurality of conductive interconnections. Memory controller 506 is configured to control 3D memory device 504. For example, memory controller 506 may be configured to operate a plurality of channel structures via word lines. Memory controller 506 can manage data stored in 3D memory device 504 and communicate with host device 508.

In some implementations, memory controller 506 is designed/configured for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 506 is designed/configured for operating in a high duty cycle environment like SSDs or embedded multi-media-cards (eMMCs) used as data storage for mobile devices, such as smartphones, tablets, laptop computers, etc., and enterprise storage arrays. Memory controller 506 can be configured to control operations of 3D memory device 504, such as read, erase, and program (or write) operations. Memory controller 506 can also be configured to manage various functions with respect to the data stored or to be stored in 3D memory device 504 including, but not limited to bad-block management, garbage collection, logical-to-physical address conversion, wear leveling, etc. In some implementations, memory controller 506 is further configured to process error correction codes (ECCs) with respect to the data read from or written to 3D memory device 504. Any other suitable functions may be performed by memory controller 506 as well, for example, formatting 3D memory device 504.

Memory controller 506 can communicate with an external device (e.g., host device 508) according to a particular communication protocol. For example, memory controller 506 may communicate with the external device through at least one of various interface protocols, such as a USB protocol, an MMC protocol, a peripheral component interconnection (PCI) protocol, a PCIexpress (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 506 and one or more 3D memory devices 504 can be integrated into various types of storage devices, for example, be included in the same package, such as a universal Flash storage (UFS) package or an eMMC package. That is, memory system 502 can be implemented and packaged into different types of end electronic products. In one example as shown in FIG. 5, memory controller 506 and a 3D memory device 504 may be integrated into a memory system 502. Memory system 502 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc.

Implementations of the subject matter and the actions and operations described in this present disclosure can be implemented in digital electronic circuitry, in tangibly-embodied computer software or firmware, in computer hardware, including the structures disclosed in this present disclosure and their structural equivalents, or in combinations of one or more of them. Implementations of the subject matter described in this present disclosure can be implemented as one or more computer programs, e.g., one or more modules of computer program instructions, encoded on a computer program carrier, for execution by, or to control the operation of, data processing apparatus. The carrier may be a tangible non-transitory computer storage medium. Alternatively, or in addition, the carrier may be an artificially-generated propagated signal, e.g., a machine-generated electrical, optical, or electromagnetic signal, that is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

It is noted that references in the present disclosure to “one embodiment,” “an embodiment,” “an example embodiment,” “some implementations,” “an implementation,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for ease of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layers.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., .+−.10%, .+−.20%, or .+−.30% of the value).

In the present disclosure, the term “horizontal/horizontally/lateral/laterally” means nominally parallel to a lateral surface of a substrate, and the term “vertical” or “vertically” means nominally perpendicular to the lateral surface of a substrate.

As used herein, the term “3D memory” refers to a three-dimensional (3D) semiconductor device with vertically oriented strings of memory cell transistors (referred to herein as “memory strings,” such as NAND strings) on a laterally-oriented substrate so that the memory strings extend in the vertical direction with respect to the substrate.

The present disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include implementations in which the first and second features may be in direct contact, and may also include implementations in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various implementations and/or configurations discussed.

The foregoing description of the specific implementations can be readily modified and/or adapted for various applications. Therefore, such adaptations and modifications are intended to be within the meaning and range of equivalents of the disclosed implementations, based on the teaching and guidance presented herein.

While the present disclosure contains many specific implementation details, these should not be construed as limitations on the scope of what is being claimed, which is defined by the claims themselves, but rather as descriptions of features that may be specific to particular implementations of particular inventions. Certain features that are described in this present disclosure in the context of separate implementations can also be implemented in combination in a single embodiment. Conversely, various features that are described in the context of a single embodiment can also be implemented in multiple implementations separately or in any suitable sub-combination. Moreover, although features may be described above as acting in certain combinations and even initially be claimed as such, one or more features from a claimed combination can in some cases be excised from the combination, and the claim may be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations also are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

The breadth and scope of the present disclosure should not be limited by any of the above-described exemplary implementations, but should be defined only in accordance with the following claims and their equivalents.

What is claimed is:

1. A method, comprising:
providing a semiconductor structure comprising a first region including a first trench structure and a second region including a second trench structure, wherein the semiconductor structure comprises a first sacrificial film covering the first trench structure, and a second sacrificial film formed on a surface of the second trench structure from an opening of the second trench structure to a bottom of the second trench structure along a first direction; and
etching at least one part of the second sacrificial film, while at least one part of the first sacrificial film remains to cover the first trench structure.

2. The method of claim 1, wherein the first trench structure is coupled to the second trench structure, and wherein the first sacrificial film is coupled to the second sacrificial film.

3. The method of claim 1, wherein, along a second direction perpendicular to the first direction, the first trench structure has a width smaller than the second trench structure.

4. The method of claim 3, further comprising:
depositing a sacrificial material over the first trench structure and the second trench structure to fill the sacrificial material in the first trench structure and form the first sacrificial film covering the filled sacrificial material in the first trench structure and to form the second sacrificial film having a first part on a top surface of the second region and a second part on an inner surface of the second trench structure.

5. The method of claim 1, wherein the second sacrificial film comprises a first part on a top surface of the second region and a second part on an internal surface of the second trench structure, and
wherein etching the at least one part of the second sacrificial film comprises:
etching the second part of the second sacrificial film away from the internal surface of the second trench structure.

6. The method of claim 5, further comprising:
changing at least one characteristic of a region of a sacrificial material, wherein the region of the sacrificial material comprises at least one of the first sacrificial film or the first part of the second sacrificial film.

7. The method of claim 6, wherein changing the at least one characteristic of the region of the sacrificial material comprises:
implanting ions into the region of the sacrificial material to change an etching rate of the region of the sacrificial material.

8. The method of claim 7, wherein implanting the ions into the region of the sacrificial material comprises:
controlling at least one of an ion implanting power, an ion implanting angle, or an ion implanting density, to implant the ions into the region of the sacrificial material.

9. The method of claim 7, wherein the sacrificial material comprises at least one of polysilicon or aluminum oxide, and wherein the ions comprise at least one of nitrogen, argon, carbon, or boron.

10. The method of claim 5, wherein a sacrificial material comprises polysilicon, and the method further comprises:
implanting ions into to a region of the sacrificial material to change the polysilicon in the region of the sacrificial material to non-polysilicon to thereby change an etching rate of the region of the sacrificial material, wherein the region of the sacrificial material comprises the first part of the second sacrificial film on the top surface of the second region.

11. The method of claim 1, wherein the second region comprises a plurality of alternating sacrificial layers and insulating layers, and
wherein the method further comprises:
after etching the at least one part of the second sacrificial film, removing the sacrificial layers in the second region through the opening of the second trench structure.

12. A semiconductor device, comprising:
an array region comprising a first slit structure extending along a first direction; and
a connection region adjacent to the array region along a second direction perpendicular to the first direction,
wherein the connection region comprises a second slit structure extending along the first direction through an insulating layer that extends along the second direction, and
wherein the insulating layer comprises an insulating material and ions distributed among the insulating material in the insulating layer.

13. The semiconductor device of claim 12, comprising a stack of conductive layers and isolating layers alternating with each other along the first direction,
wherein each of the first slit structure and the second slit structure extends through the stack of conductive layers and isolating layers, and
wherein the insulating layer is closer to an end of the second slit structure than the stack of conductive layers and isolating layers along the first direction.

14. The semiconductor device of claim 13, wherein the connection region comprises a plurality of contact structures extending through the stack of conductive layers and isolating layers, and
wherein at least one of the conductive layers is coupled to a corresponding contact structure of the plurality of contact structures.

15. The semiconductor device of claim 14, wherein the connection region comprises first and second opposite ends along the first direction, and
wherein each of the plurality of contact structures is coupled out to a conductive contact at the first end or the second end.

16. The semiconductor device of claim 13, wherein the array region comprises a plurality of channel structures extending through the stack of conductive layers and isolating layers.

17. The semiconductor device of claim 12, wherein the first slit structure connects the second slit structure along the second direction, and
wherein, along a third direction perpendicular to the first direction and the second direction, a width of the first slit structure is smaller than a width of the second slit structure.

18. The semiconductor device of claim 13, wherein the insulating layer comprises a first surface and a second surface along the first direction, the first surface being closer to the end of the second slit structure along the first direction than the second surface, and wherein a first concentration of the ions adjacent to the first surface is higher than a second concentration of the ions adjacent to the second surface of the insulating layer.

19. A method comprising:
providing a semiconductor structure comprising a first region including a first trench structure and a second region including a second trench structure, wherein the semiconductor structure comprises a first sacrificial film covering the first trench structure, and a second sacrificial film formed on a surface of the second trench structure from an opening of the second trench structure to a bottom of the second trench structure, and wherein the second sacrificial film comprises a first part on a top surface of the second region and a second part on an internal surface of the second trench structure;
changing at least one characteristic of a region of a sacrificial material, wherein the region of the sacrificial material comprises at least one of the first sacrificial film or the first part of the second sacrificial film; and
etching the second part of the second sacrificial film away from the internal surface of the second trench structure, while at least one part of the first sacrificial film remains to cover the first trench structure.

20. The method of claim 19, wherein changing the at least one characteristic of the region of the sacrificial material comprises:
implanting ions into the region of the sacrificial material to change an etching rate of the region of the sacrificial material.
